(19) United States
(12) Patent Application Publication
(10) Pub. No.: US 2026/0136885 A1
(43) Pub. Date: May 14, 2026

(54) STAGE

(71) Applicant: NHK SPRING CO., LTD., Yokohama-shi (JP)

(72) Inventors: Toshihiko HANAMACHI, Yokohama-shi (JP); Shuhei MOROTA, Yokohama-shi (JP); Masaru TAKIMOTO, Yokohama-shi (JP); Yoshihito ARAKI, Yokohama-shi (JP); Hibiki YOKOYAMA, Yokohama-shi (JP); Masahiro FUJII, Yokohama-shi (JP)

(21) Appl. No.: 19/442,700

(22) Filed: Jan. 7, 2026

Related U.S. Application Data
(62) Division of application No. 17/463,786, filed on Sep. 1, 2021.
Application No. 17/463,786 is a continuation of application No. PCT/JP2020/007433, filed on Feb. 25, 2020.

(30) Foreign Application Priority Data
Mar. 1, 2019 (JP) 2019-037589

(51) Int. Cl. H10P 72/72; C23C 4/12; H01J 37/32

(52) U.S. Cl. CPC H10P 72/722; C23C 4/12; H01J 37/32715; H01J 2237/334

(57) ABSTRACT

A stage includes a base material having a first surface and a second surface adjacent to the first surface, and an insulating film including a plurality of particles, each of the plurality of particles having a flat surface. The flat surface included in the insulating film is provided along the first surface and the second surface. The base material includes a third surface in a direction 180 degrees opposite to the first surface, and a part of the flat surface included in the insulating film is provided along the third surface, and a surface obtained by extending the first surface and a surface obtained by extending the second surface intersect at 90 degrees. The base material includes a third surface in a direction 180 degrees opposite to the first surface, and a part of the flat surface included in the insulating film is provided along the third surface.

### CROSS-REFERENCE TO RELATED APPLICATIONS

This application is a Division of U.S. patent application Ser. No. 17/463,786, filed on Sep. 1, 2021, which is a U.S. continuation application filed under 35 U.S.C. § 111(a), of International Application No. PCT/JP 2020/007433, filed on Feb. 25, 2020, which claims priority to Japanese Patent Application No. 2019-037589, filed on Mar. 1, 2019, the disclosures of which are incorporated herein by reference.

### FIELD

An embodiment of the present invention relates to a stage and a method of manufacturing the stage, for example, a stage for placing a substrate and a method of manufacturing the stage for placing the substrate.

### BACKGROUND

Semiconductor devices are installed in almost all electronic devices and play an important role for the functions of the electronic devices. Semiconductor devices utilize semiconductor characteristics possessed by silicon, etc. Semiconductor devices are constructed by stacking a semiconductor film, an insulating film, and a conductive film on a substrate and patterning these films. These films are stacked by vapor deposition, sputtering, chemical vapor phase deposition (CVD), or substrate chemical reactions, and are patterned by a photolithography process. The photolithography process includes the formation of a resist on the films that are subjected to patterning, the exposure of the resist, the formation of a resist mask by development, the partial removal of these films by etching, and the removal of the resist mask.

The characteristics of the films described above depend largely on the conditions for forming the films or the conditions for patterning. One of the above conditions is a voltage applied to a mounting table (hereinafter referred to as stage) for installing a substrate. For example, the voltage applied to the stage included in an etching device has been increasing with the miniaturization of recent semiconductor devices, since the ratio of the diameter of a hole to be processed and the thickness of the film to be processed is increased. As the voltage applied to the stage increases, withstand voltages of members included in the stage need to be improved. The members included in the stage may be, for example, a cooling plate and an electrostatic chuck, or the like. For example, Japanese U.S. Pat. No. 6,027,407 and Japanese Registered Utility Model No. 2600558 disclose a stage in which an insulating film is formed on the surface by using a thermal spraying method to improve the withstand voltage.

### SUMMARY

One embodiment of the present invention is a stage. The stage includes a base material having a first surface and a second surface adjacent to the first surface, and an insulating film consisting of a plurality of particles each having a flat surface. A part of the flat surface included in the insulating film is provided along the first surface and the second surface.

In another embodiment, the base material includes a third surface in a direction 180 degrees opposite to the first surface, and a part of the flat surface included in the insulating film may be provided along the third surface.

In another embodiment, a surface obtained by extending the first surface and a surface obtained by extending the second surface may be provided to intersect at 90 degrees.

In another embodiment, a ratio of an area of a void to a predetermined area of the insulating film may be 5% or less.

In another embodiment, the base material may have a flow path through which a liquid flows.

In another embodiment, an electrostatic chuck may be provided on the insulating film.

One embodiment of the present invention is a method of manufacturing a stage, the method includes spraying an insulator onto a first surface from a perpendicular direction to the first surface while moving in a parallel direction to the first surface of the base material, and spraying the insulator onto a second surface from a perpendicular direction to the second surface while moving in a parallel direction to the second surface of the base material adjacent to the first surface.

In another embodiment, the method may include spraying the insulator onto a third surface from a perpendicular direction to the third surface while moving in a parallel direction to the third surface of the base material in a direction 180 degrees opposite to the first surface.

In another embodiment, a surface obtained by extending the first surface and a surface obtained by extending the second surface may be formed to intersect at 90 degrees.

In another embodiment, the spraying of the insulator onto the first surface and the spraying of the insulator onto the second surface may be continuously performed.

In another embodiment, the spraying of the insulator onto the first surface and the spraying of the insulator onto the second surface may be alternately repeated.

In another embodiment, the spraying of the insulator onto the third surface, the spraying of the insulator onto the second surface, and the spraying of the insulator onto the first surface may be continuously performed.

In another embodiment, the flat surface of some of the particles included in the insulating film may be sprayed so as to be provided along the first surface and the second surface.

In another embodiment, the flat surface of some of the particles included in the insulating film may be sprayed so as to be provided along the third surface.

### BRIEF DESCRIPTION OF DRAWINGS

FIG. 1A is a perspective view showing a configuration of a stage according to an embodiment of the present invention.

FIG. 1B is a cross-sectional view showing a configuration of a stage according to an embodiment of the present invention.

FIG. 1C is a cross-sectional view showing a configuration of a stage according to an embodiment of the present invention.

FIG. 2A is a perspective view showing a method of manufacturing a stage according to an embodiment of the present invention.

FIG. 2B is a perspective view showing a method of manufacturing a stage according to an embodiment of the present invention.

FIG. 2C is a perspective view showing a method of manufacturing a stage according to an embodiment of the present invention.

FIG. 3A is a perspective view showing a method of manufacturing a stage according to an embodiment of the present invention.

FIG. 3B is a perspective view showing a method of manufacturing a stage according to an embodiment of the present invention.

FIG. 3C is a perspective view showing a method of manufacturing a stage according to an embodiment of the present invention.

FIG. 4A is a cross-sectional view for explaining a part of a corner portion of a conventional stage.

FIG. 4B is a cross-sectional view for explaining a part of a corner portion of a conventional stage.

FIG. 4C is a cross-sectional view for explaining a part of a corner portion of a conventional stage.

FIG. 5A is a cross-sectional view showing a part of a corner portion of a stage according to an embodiment of the present invention.

FIG. 5B is a cross-sectional view showing a part of a corner portion of a stage according to an embodiment of the present invention.

FIG. 6A is a cross-sectional view showing a part of a corner portion of a stage according to an embodiment of the present invention.

FIG. 6B is a cross-sectional view showing a part of a corner portion of a stage according to an embodiment of the present invention.

FIG. 7 is an example of images obtained by capturing a part of a corner portion of a stage according to an embodiment of the present invention with an electron microscope.

FIG. 8A is a perspective view showing a method of manufacturing a stage according to an embodiment of the present invention.

FIG. 8B is a perspective view showing a method of manufacturing a stage according to an embodiment of the present invention.

FIG. 8C is a perspective view showing a method of manufacturing a stage according to an embodiment of the present invention.

FIG. 9 is a schematic cross-sectional view of a film processing device including a stage according to an embodiment of the present invention.

FIG. 10A is an example of images obtained by capturing a part of a corner portion of a stage according to an embodiment of the present invention with an electron microscope.

FIG. 10B is an example of images obtained by capturing a part of a corner portion of a stage according to an embodiment of the present invention with an electron microscope.

FIG. 11 is a diagram showing a dielectric breakdown voltage of a stage according to an embodiment of the present invention.

FIG. 12A is a perspective view showing a configuration of a stage according to an embodiment of the present invention.

FIG. 12B is a cross-sectional view showing a configuration of a stage according to an embodiment of the present invention, and

FIG. 12C is a cross-sectional view showing a configuration of a stage according to an embodiment of the present invention.

### DESCRIPTION OF EMBODIMENTS

Hereinafter, embodiments of the invention disclosed in the present application will be described with reference to the drawings. However, the present invention can be implemented in various forms without departing from the gist thereof and should not be construed as being limited to the description of the following exemplary embodiments.

For the sake of clarity of description, the drawings may be schematically represented with respect to widths, thicknesses, shapes, and the like of the respective portions compared with actual embodiments. However, they are merely an example and do not limit the interpretation of the present invention. In this specification and respective drawings, components having the same functions as those described with reference to the preceding drawings are denoted by the same reference numerals, and a duplicate description thereof may be omitted.

In the present invention, when a single film is processed to form a plurality of films, this plurality of films may have different functions and roles. However, this plurality of films is derived from films formed as the same layer in the same process and has the same layer structure and the same material. Therefore, the plurality of films is defined as existing in the same layer.

In this specification and the drawings, when multiple portions of one configuration are distinguished, for example, the same reference numerals are used, and a hyphen and a natural number are used.

In a conventional thermal spraying method, for example, a method of spraying an insulating film on a stage is changed for each surface of the stage. Therefore, gaps or voids have formed in the insulating film at an interface between the surfaces of the stage (hereinafter sometimes referred to as corner portion). Then, a withstand voltage of the sprayed insulating film decreased due to the gaps or voids. Therefore, in the stage, it is a challenge to improve the withstand voltage (hereinafter sometimes referred to as dielectric breakdown voltage) of the members contained in the stage to be sprayed by reducing the gaps or voids in the insulating film sprayed using the thermal spraying method.

It is one of purposes of an embodiment of the present invention to provide a stage having a high withstand voltage and a method of manufacturing the stage.

Some of the following embodiments illustrate stages having a high withstand voltage and methods of manufacturing the stages.

### 1. First Embodiment

In this embodiment, a stage 122 according to an embodiment of the present invention will be described.

### 1-1. Configuration of Stage

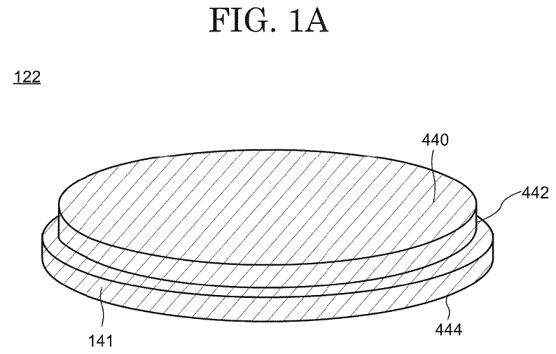

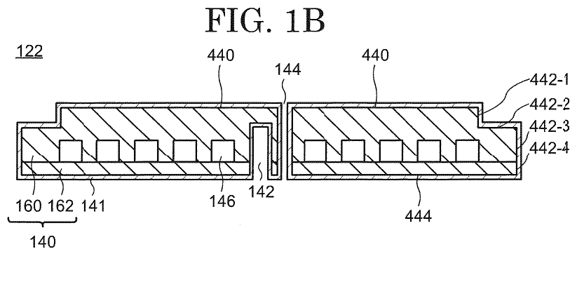

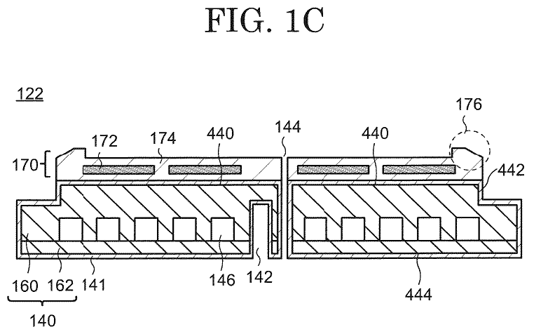

FIGS. 1A to 1C shows a cross-sectional view of the stage 122. As shown in FIGS. 1A and 1B, the stage 122 has a support plate 140 and a first insulating film 141.

The support plate 140 has at least a first surface 440, a second surface 442 adjacent to the first surface 440, and a third surface 444. The support plate 140 has a first base material 160 and a second base material 162. The first base material 160 has the first surface 440 and the second surface 442, and the second base material 162 has the third surface 444. The first insulating film 141 is provided on the first base material 160 and the second base material 162 by a thermal spraying method. That is, the first insulating film 141 is provided on the first surface 440, the second surface 442, and the third surface 444. The second surface 442 may include all of a portion of a second surface 442-1, a second surface 442-2, a second surface 442-3, and a second surface 442-4. In an embodiment of the present invention, although an example is shown in which the first insulating film 141 is provided on all of the third surface 444 is shown, the first insulating film 141 may be provided on a part of the third surface 444.

A surface obtained by extending the first surface 440 and a surface obtained by extending the second surface 442-1 are formed to intersect at 90 degrees or approximately 90 degrees to each other. A surface obtained by extending the second surface 442-1 and a surface obtained by extending the second surface 442-2 are formed to intersect at 90 degrees or approximately 90 degrees to each other. A surface obtained by extending the second surface 442-2 and a surface obtained by extending the second surface 442-3 are formed to intersect at 90 degrees or approximately 90 degrees to each other. A surface obtained by extending the second surface 442-3 and a surface obtained by extending the second surface 442-4 are formed to intersect at 90 degrees or approximately 90 degrees to each other. A surface obtained by extending the second surface 442-4 and a surface obtained by extending the third surface 444 are formed to intersect at 90 degrees or approximately 90 degrees to each other. The first surface 440 and the third surface 444 are formed in a direction 180 degrees or approximately 180 degrees opposite to each other.

The main material of the first base material 160 and the second base material 162 is metal or a ceramic, and for example, titanium (Ti), aluminum (Al), stainless steel, or an oxide containing these or the like can be used. The support plate 140 may be provided with an opening 142 to arrange a temperature sensor on a bottom surface. A thermocouple or the like can be used for the temperature sensor. In an embodiment, although and example is shown in which the first insulating film 141 is provided on the inner wall of the opening 142, the first insulating film 141 may be provided on a part of the inner wall of the opening 142.

A groove (flow path) 146 may be provided in the support plate 140 of the stage 122 for recirculating a medium for controlling the temperature of a substrate. A liquid medium such as water, an alcohol such as isopropanol or ethylene glycol, or silicone oil can be used as the medium. The groove 146 is formed in one or both of the first base material 160 and the second base material 162, and then the first base material 160 and the second base material 162 are joined by brazing or the like. The medium may be used in both cases when the stage 122 is cooled or heated.

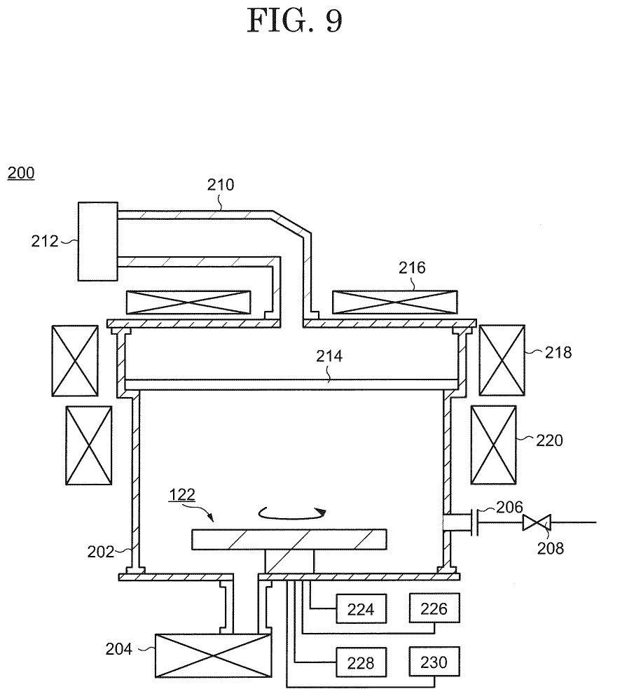

Using a temperature controller 228 illustrated in FIG. 9, which will be described later, the temperature of the support plate 140 can be controlled by flowing a temperature-controlled medium through the groove 146.

Any known material can be used as the first insulating film 141 as long as it satisfies a desired withstand voltage and can be sprayed by the thermal spraying method. For example, one or more kinds of oxides of alkaline earth metal, rare earth metal, aluminum (Al), tantalum (Ta) and silicon (Si) are used as the material used for the first insulating film 141. Specific examples include aluminum oxide (Al₂O₃) and magnesium oxide (MgO), and the like.

The material used for the first insulating film 141 may include an inorganic insulator. Specific examples of the inorganic insulator include aluminum oxide, titanium oxide, chromium oxide, zirconium oxide, magnesium oxide, yttrium oxide, or a composite oxide thereof.

The thermal spraying method used in this specification and the like may be, for example, a Rokide thermal spraying method, a plasma spraying method, or a thermal spraying method in which these methods are combined.

Optionally, the stage 122 may have one or more through hole(s) 144 penetrating the support plate 140. A helium introduction tube may be provided in a chamber 202 illustrated in FIG. 9, which will be described later, so as to allow a highly thermally conductive gas, such as helium, to flow through the through hole 144. This allows the gas to flow through a gap between the stage 122 and the substrate and efficiently convey thermal energy of the stage 122 to the substrate. In an embodiment of the present invention, although an example is shown in which the first insulating film 141 is provided on the inner wall of the through hole 144, the first insulating film 141 may be provided on a part of the inner wall of the through hole 144.

As illustrated in FIG. 1C, the stage 122 may further include an electrostatic chuck 170 as a mechanism for securing the substrate onto the stage 122. The electrostatic chuck 170 may have a structure in which, for example, electrostatic chuck electrodes 172 are covered with an insulating film 174. By applying a high voltage (several hundred V to several thousand V) to the electrostatic chuck electrodes 172, it is possible to fix the substrate due to a Coulomb force between a charge generated in the electrostatic chuck electrodes 172 and a charge generated on the back surface of the substrate and having the opposite polarity to the charge generated in the electrostatic chuck electrodes 172. A ceramic such as aluminum oxide or aluminum nitride, and boron nitride can be used as the insulator. The insulating film 174 does not have to be completely insulated and may have some degree of conductivity (e.g., resistance ratio in the order of 10⁹ Ωcm to 10¹² Ωcm). In this case, the above-described ceramic is doped with a metal oxide such as titanium oxide, zirconium oxide, or hafnium oxide to form the insulating film 174. A rib 176 may be provided around the electrostatic chuck 170 to determine the position of the substrate.

### 1-2. Manufacture of Stage

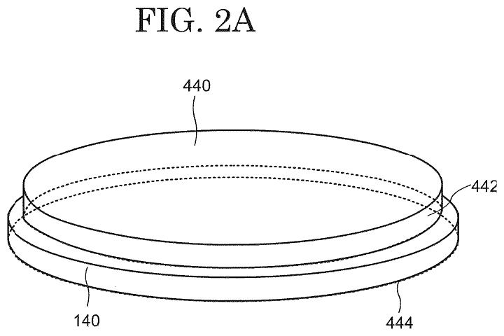

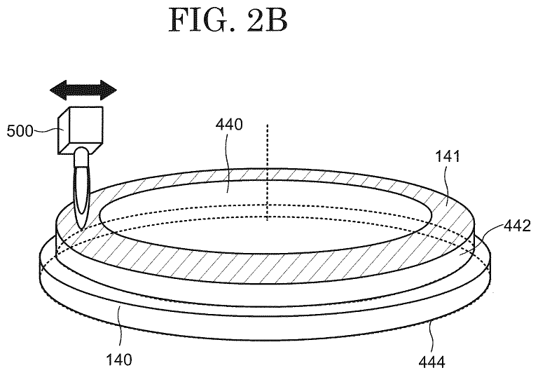

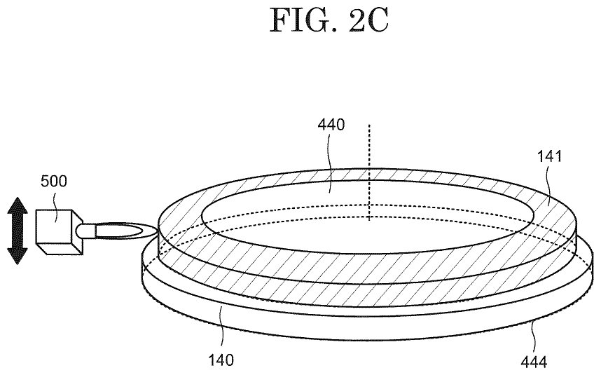

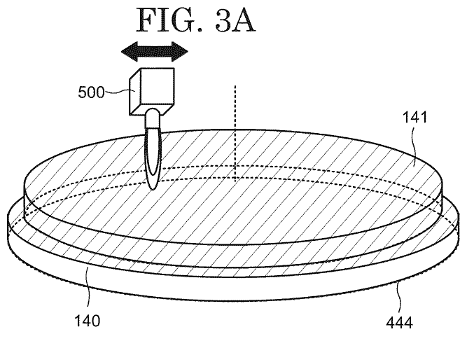

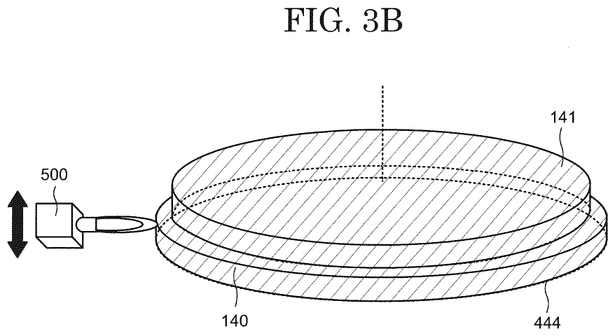

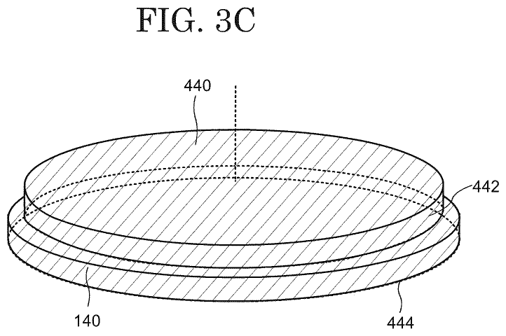

FIGS. 2A to 3C are cross-sectional views showing a first method of manufacturing the stage 122. Descriptions of the same or similar structures as those of FIG. 1A, FIG. 1B, or FIG. 1C may be omitted.

The first method of manufacturing the stage 122 will be described with reference to FIGS. 2A to 3C. First, as shown in FIG. 2A, the support plate 140 is prepared.

Next, as shown in FIG. 2B, the first insulating film 141 is formed on at least a part of the first surface 440 while moving a thermal sprayer 500 included in the thermal spraying device in a parallel direction to the first surface 440 of the support plate 140. At this time, the thermal sprayer 500 may repeatedly move from an end of the support plate 140 toward the approximate center of the first surface 440 of the support plate 140 and from the approximate center of the support plate 140 toward the end of the support plate 140 and the first insulating film 141 may be formed on at least a part of the first surface 440 while moving in a zigzag manner. Forming the first insulating film 141 on the first surface 440 using the thermal sprayer 500 included in the thermal spraying device may be referred to as forming the first insulating film 141 on the first surface 440 using the thermal spraying method. At this time, when the direction in which the particles sprayed from the thermal sprayer 500 are sprayed onto the first surface 440 is a thermal spraying direction, the thermal spraying direction and the first surface 440 may be substantially perpendicular or perpendicular. Movement of the thermal sprayer 500 in a parallel direction to the first surface 440 may be in one direction, or both one direction and 180 degrees in an opposite direction, as shown in FIG. 2B. By forming the first insulating film 141 on the first surface 440 while moving in both one direction and 180 degrees in an opposite direction, the first insulating film 141 can be uniformly formed on the first surface 440.

Next, as shown in FIG. 2C, the first insulating film 141 is formed on at least a part of the second surface 442 while moving the thermal sprayer 500 in a parallel direction to the second surface 442. At this time, the thermal sprayer 500 may repeatedly move from one end of the second surface 442 (e.g., the first surface 440 side) toward the other end of the second surface 442 (e.g., the third surface 444 side) and from the other end of the second surface 442 toward one end of the second surface 442, and the first insulating film 141 may be formed on at least a part of the second surface 442 while moving the thermal sprayer 500 in a zigzag manner. Forming the first insulating film 141 on the second surface 442 using the thermal sprayer 500 included in the thermal device may be referred to as forming the first insulating film 141 on the second surface 442 using the thermal spraying method. At this time, when the direction in which the particles sprayed from the thermal sprayer 500 are sprayed onto the second surface 442 is the thermal spraying direction, the thermal spraying direction and the second surface 442 may be substantially perpendicular or perpendicular. Movement of the thermal sprayer 500 in a parallel direction to the second surface 442 may be in one direction, or in both one direction and 180 degrees in an opposite direction, as shown in FIG. 2C. By forming the first insulating film 141 on the second surface 442 while moving the thermal sprayer 500 in both one direction and 180 degrees in an opposite direction, the first insulating film 141 can be uniformly formed on the second surface 442.

Next, similar to the method described in FIG. 2B, again, the first insulating film 141 is formed on the first surface 440 as shown in FIG. 3A. Subsequently, similar to the method described in FIG. 2C, again, the first insulating film 141 is formed on the second surface 442 as shown in FIG. 3B.

As described above, by forming the first insulating film 141 on each surface, the first insulating film 141 can be provided on the support plate 140 as shown in FIG. 3C. Further, for example, as shown in FIG. 1C, the stage 122 can be manufactured by joining the support plate 140 and the electrostatic chuck 170. The support plate 140 and the electrostatic chuck 170 can be joined, for example, by welding, screwing, or brazing. The braze used in the brazing process includes an alloy containing silver, copper, and zinc, an alloy containing copper and zinc, copper containing trace amounts of phosphorus, aluminum, and alloys thereof, an alloy containing titanium, copper, and nickel, an alloy containing titanium, zirconium, and copper, and an alloy containing titanium, zirconium, copper, and nickel, and the like.

As described above with reference to FIGS. 2A, 2B, 2C, 3A, 3B, 3C, and 1A, by alternately repeating the formation of the first insulating film 141 on the first surface 440 and the formation of the first insulating film 141 on the second surface 442, the first insulating film 141 can be uniformly formed on the first surface 440 and the second surface 442 of the support plate 140. By alternately repeating the formation of the first insulating film 141 on the first surface 440 and the formation of the first insulating film 141 on the second surface 442, it is possible to suppress the generation of a gap or void in a corner portion between the first surface 440 and the second surface 442. The first insulating film 141 formed on the first surface 440 and the first insulating film 141 formed on the second surface 442 may overlap by alternately repeating the formation of the first insulating film 141 on the first surface 440 and the formation of the first insulating film 141 on the second surface 442. By overlapping the first insulating film 141 formed on the first surface 440 and the first insulating film 141 formed on the second surface 442, it is possible to suppress the generation of a gap or void in the corner portion between the first surface 440 and the second surface 442.

For example, the first insulating film 141 may be uniformly formed on a circular support plate 140 of approximately 30 cm by repeating formation of the first insulating film 141 on at least a part of the first surface 440 while moving the device sprayer 500 included in the thermal sprayer 1 mm in a parallel direction to the first surface 440 and the formation of the first insulating film 141 on at least a part of the second surface 442 while moving the thermal sprayer 500 included in the thermal sprayer 1 mm in a parallel direction to the second surface 442.

Optionally, the first insulating film 141 may be formed on at least a part of the third surface 444 while moving the thermal sprayer 500 in a parallel direction to the third surface 444. By repeatedly moving the thermal sprayer 500 from the end of the support plate 140 toward the approximate center of the third surface 444 of the support plate 140 and moving the thermal sprayer 500 from the approximate center of the support plate 140 toward the end of the support plate 140, the first insulating film 141 may be formed on at least a part of the third surface 444 while moving the thermal sprayer 500 in a zigzag manner. At this time, the first insulating film 141 may be uniformly formed on the first surface 440, the second surface 442, and the third surface 444 of the support plate 140 by repeatedly forming the first insulating film 141 on at least a part of the first surface 440, the first insulating film 141 on at least a part of the second surface 442, and the first insulating film 141 on at least a part of the third surface 444.

1-3. Comparison between a Corner Portion of Support Plate of a Conventional Stage and a Corner Portion of Support Plate 140 of Stage 122 According to an Embodiment of the Present Invention

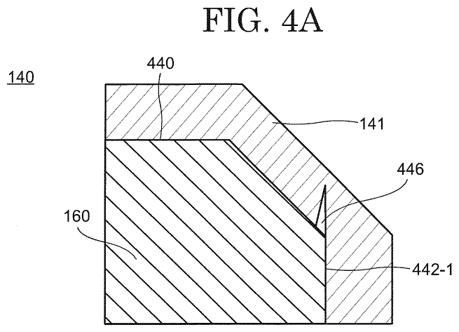

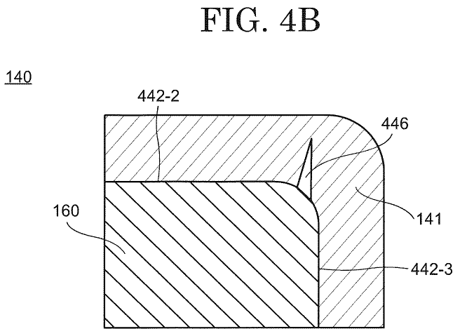

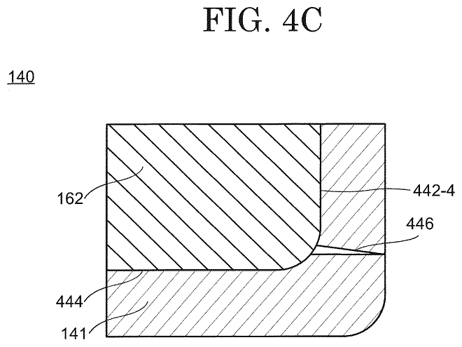

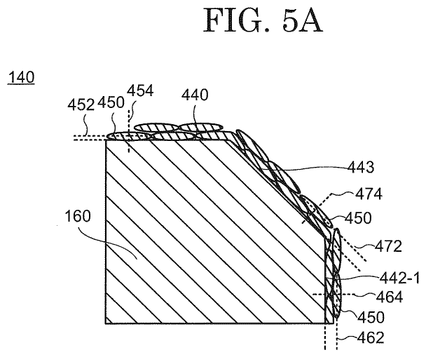

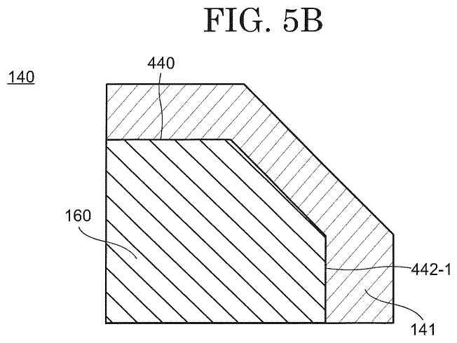

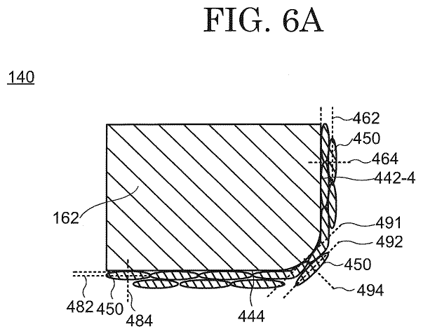

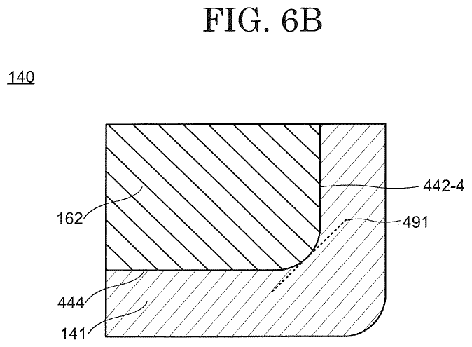

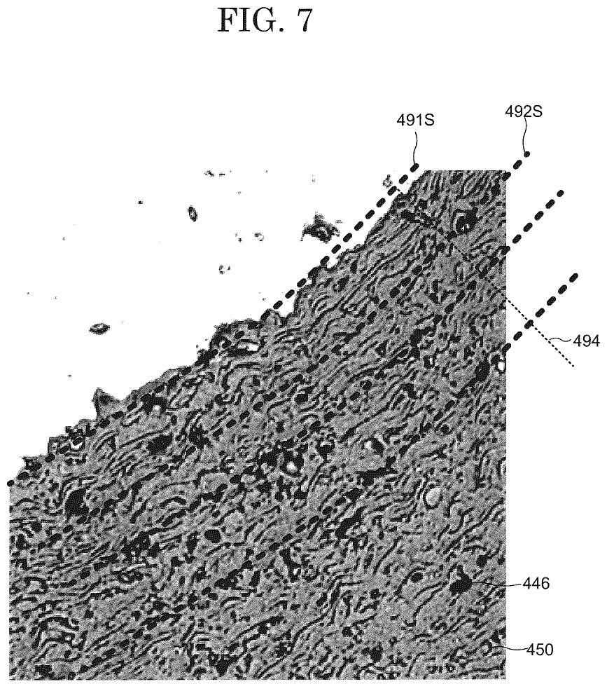

FIGS. 4A to 4C is a cross-sectional view for explaining a part of a corner portion of the support plate of the conventional stage. FIGS. 5A to 6B are cross-sectional views showing a part of the corner portion of the support plate 140 of the stage 122 according to an embodiment of the present invention. FIG. 7 is an example of images obtained by capturing a part of the corner portion of the support plate 140 of the stage 122 according to an embodiment of the present invention. Description of the same or similar components as those of FIGS. 1A to 3C may be omitted. In the following explanation, the stage 122 having the configuration shown in FIG. 1B will be exemplified.

As shown in FIG. 4A, a corner portion between the first surface 440 and the second surface 442-1 has a C-chamfered shape. In FIG. 4B, as an example, a corner portion between the second surface 442-2 and the second surface 442-3 has a curvature. In FIG. 4C, as an example, a corner portion between the second surface 442-4 and the third surface 444 has a curvature. Conventionally, the first insulating film 141 formed on the corner portion between the first surface 440 and the second surface 442-1, the first insulating film 141 formed on the corner portion between the second surface 442-2 and the second surface 442-3, and the first insulating film 141 formed on the corner portion between the second surface 442-4 and the third surface 444 include large gaps or voids 446. The corner portion between the first surface 440 and the second surface 442-1 may have a curvature, the corner portion between the second surface 442-2 and the second surface 442-3 may have a C-chamfered shape, and the corner portion between the second surface 442-4 and the third surface 444 may have a C-chamfered shape.

On the other hand, in FIG. 5B, the corner portion between the first surface 440 and the second surface 442-1 of the support plate 140 of the stage 122 has a C-chamfered shape. As shown in FIG. 5B, the first insulating film 141 formed on the corner portion between the first surface 440 and the second surface 442-1 does not include the large gaps or voids 446 and is a uniform film.

As shown in FIG. 5A, in the support plate 140 of the stage 122, the first insulating film 141 formed by the thermal spraying method is composed of a plurality of particles 450 having a flat shape on the first surface 440. A flat surface 452 of at least some of the particles 450 of the plurality of particles 450 is formed by the thermal spraying method along a surface parallel or substantially parallel to the first surface 440. Particles sprayed by the thermal sprayer 500 are the particles 450. A direction 454 perpendicular or substantially perpendicular to the flat surface 452 and a direction perpendicular or substantially perpendicular to the first surface 440 are parallel or substantially parallel to each other and are also parallel or substantially parallel to the thermal spraying direction in which the particles 450 sprayed by the thermal sprayer 500 are sprayed onto the first surface 440.

Similar to the first surface 440, on the second surface 442-1, the first insulating film 141 formed by the thermal spraying method is composed of the plurality of particles 450 having a flat shape, and a flat surface 462 of at least some of the particles 450 of the plurality of particles 450 is formed by the thermal spraying method along a surface parallel or substantially parallel to the second surface 442-1. Particles sprayed by the thermal sprayer 500 are the particles 450. Further, the direction 464 perpendicular or substantially perpendicular to the flat surface 462 and the direction perpendicular or substantially perpendicular to the second surface 442-1 are parallel or substantially parallel to each other and are also parallel or substantially parallel to the thermal spraying direction in which the particles 450 sprayed by the thermal sprayer 500 are sprayed onto the second surface 442-1.

Similar to the first surface 440 and the second surface 442-1, on a corner surface 443, the first insulating film 141 formed by the thermal spraying method is composed of the plurality of particles 450 having a flat shape, and a flat surface 472 of at least some of the particles 450 of the plurality of particles 450 is formed by the thermal spraying method along a surface parallel or substantially parallel to the corner surface 443. Particles sprayed by the thermal sprayer 500 are the particles 450. Further, a direction 474 perpendicular or substantially perpendicular to the flat surface 472 and a direction perpendicular or substantially perpendicular to the corner surface 443 are parallel or substantially parallel to each other and are also parallel or substantially parallel to the thermal spraying direction in which the particles 450 sprayed by the thermal sprayer 500 are sprayed onto the corner surface 443.

In FIG. 6B, the corner portion between the second surface 442-4 and the third surface 444 of the support plate 140 of the stage 122 has a curvature. As shown in FIG. 6B, the first insulating film 141 formed on the corner portion between the second surface 442-4 and the third surface 444 does not contain the large gaps or voids 446 and is a uniform film.

As shown in FIG. 6A, in the support plate 140 of the stage 122 according to an embodiment of the present invention, at the third surface 444 disposed in a direction 180 degrees opposite to the first surface 440, the first insulating film 141 formed by the thermal spraying method is composed of the plurality of particles 450 having a flat shape. A flat surface 482 of at least some of the particles 450 of the plurality of particles 450 is formed by the thermal spraying method parallel or substantially parallel to the third surface 444. Particles sprayed by the thermal sprayer 500 are the particles 450. A direction 484 perpendicular or substantially perpendicular to the flat surface 482 and the direction perpendicular or substantially perpendicular to the third surface 444 are parallel or substantially parallel to each other and are also parallel or substantially parallel to the thermal spraying direction in which the particles 450 sprayed by the thermal sprayer 500 are sprayed onto the third surface 444.

Similar to the third surface 444, in the second surface 442-4, the first insulating film 141 formed by the thermal spraying method is composed of the plurality of particles 450 having a flat shape. The configuration of the plurality of particles 450 formed on the second surface 442-4 is the same as the configuration of the plurality of particles 450 formed on the second surface 442-1 shown in FIG. 5A, and therefore the explanation thereof is omitted here.

Similar to the third surface 444 and the second surface 442-4, when one tangent surface with respect to each point constituting the corner portion between the third surface 444 and the second surface 442-4 is defined as a surface 491, also in the surface 491, the first insulating film 141 formed by the thermal spraying method is also composed of the plurality of particles 450 having a flat shape, and a flat surface 492 of at least some of the particles 450 of the plurality of particles 450 is formed by the thermal spraying method along a surface parallel or substantially parallel to the surface 491. Particles sprayed by the thermal sprayer 500 are the particles 450. Furthermore, the direction 494 perpendicular or substantially perpendicular to the flat surface 492 and the direction perpendicular or substantially perpendicular to the surface 491 are parallel or substantially parallel to each other and are also parallel or substantially parallel to the thermal spraying direction in which the particles 450 sprayed by the thermal sprayer 500 are sprayed onto the corner surface 491.

In FIG. 7, a curved surface 491S and a curved surface 492S formed by the plurality of particles 450 are shown by approximate guidelines (dot line). As shown in FIG. 7, in the curved surface 491S and the curved surface 492S, tangent surfaces at each point constituting the respective curved surfaces are parallel or substantially parallel to each other. That is, the direction 494 perpendicular or substantially perpendicular to the flat surface 492 and the direction perpendicular or substantially perpendicular to the tangent surfaces at each point constituting the respective curved surfaces are parallel or substantially parallel to each other and are also parallel or substantially parallel to the thermal spraying direction in which the particles 450 sprayed by the thermal sprayer 500 are sprayed onto the corner portion. In the stage according to an embodiment of the present invention illustrated in FIG. 7, an example that the size of the particles is about 25 μm is shown using aluminum oxide as the material of the first insulating film 141.

In the stage 122 according to an embodiment of the present invention, forming the first insulating film 141 from a perpendicular direction to the first surface 440 while moving the thermal sprayer 500 in a parallel direction to the first surface 440 of the support plate 140 by the thermal spraying method, and forming the first insulating film 141 from a perpendicular direction to the second surface 442 while moving the thermal sprayer 500 in a parallel direction to the second surface 442 adjacent to the first surface 440 by the thermal spraying method are alternately repeated. Thus, the flat surface of at least some of the particles 450 constituting the first insulating film 141 can be formed along a surface parallel or substantially parallel to the first surface 440 and the second surface 442.

The first insulating film 141 formed on the first surface 440 and the first 141 formed on the second surface 442 are formed to overlap each other. Consequently, the first insulating film 141 formed on the first surface 440, the second surface 442, and a corner portion of the first surface 440 and the second surface 442 becomes a uniform film substantially free of gaps or voids. Therefore, since the first insulating film 141 is densely formed on the support plate 140, a dielectric breakdown voltage of the support plate 140 is improved. Therefore, by applying the present invention to the stage and the method of manufacturing the stage, it is possible to provide the stage and the method of manufacturing the stage having a high withstand voltage.

### 2. Second Embodiment

In this embodiment, a second method of manufacturing the stage 122 according to an embodiment of the present invention will be described. Description of the same or similar configuration as that of the first embodiment may be omitted.

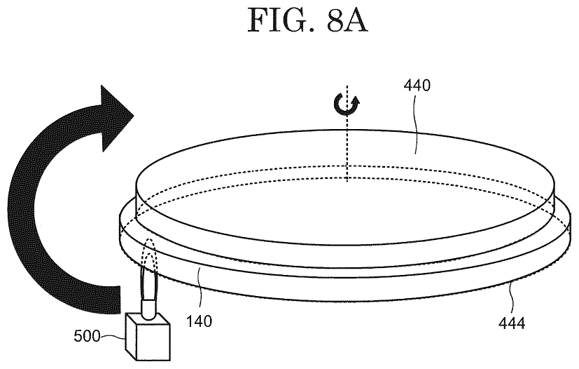

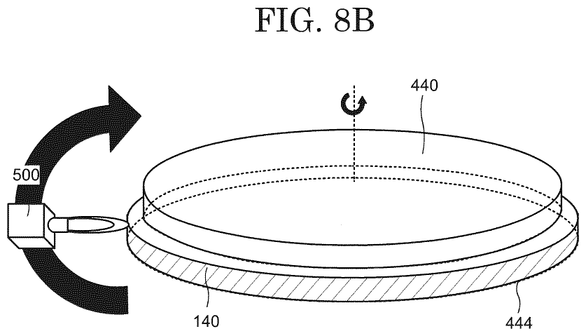

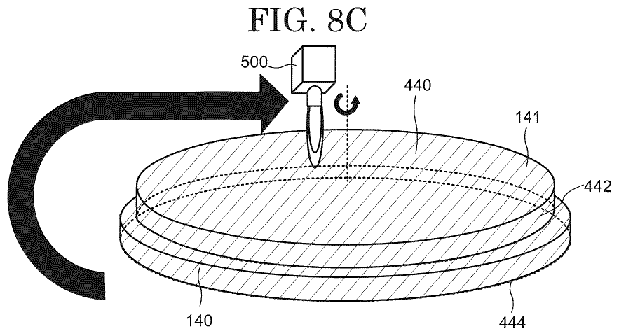

FIGS. 8A to 8C shows a second method of manufacturing the stage 122 according to an embodiment of the present invention. The second method of manufacturing the stage 122 is different from the first method of manufacturing the stage 122 shown in the first embodiment in that the formation of the first insulating film 141 on the third surface 444, the formation of the first insulating film 141 on the second surface 442, and the formation of the first insulating film 141 on the first surface 440 are performed while moving the thermal sprayer 500 continuously and in one direction. In the description of the second method of manufacturing the stage 122 below, the differences from the first manufacturing method will be mainly described.

First, since preparing the support plate 140 is the same as FIG. 2A shown in the first embodiment, a description thereof will be omitted.

Next, as shown in FIG. 8A, the support plate 140 is rotated about an axis substantially perpendicular to the approximate center of the first surface 440 of the support plate 140, and the first insulating film 141 is formed on at least a part of the third surface 444 while moving the thermal sprayer 500 included in the thermal spraying device in a parallel direction to the third surface 444.

Next, as shown in FIG. 8B, forming the first insulating film 141 on the second surface 442 using the thermal sprayer 500 is performed while moving the thermal sprayer 500 continuously and in one direction from a parallel direction to the third surface 444 along a parallel direction to the second surface 442. A method similar to the first method of manufacturing the stage 122 shown in the first embodiment can be used, for forming the first insulating film 141 on the second surface 442 using the thermal sprayer 500. The movement of the thermal sprayer 500 is continuous and unidirectional. Thus, by forming the first insulating film 141 from the third surface 444 to the second surface 442, the first insulating film 141 can be uniformly formed on the third surface 444 and the second surface 442.

Next, as shown in FIG. 8C, forming the first insulating film 141 on the first surface 440 using the thermal sprayer 500 is performed while moving the thermal sprayer 500 continuously and in one direction from a parallel direction to the second surface 442 along a parallel direction to the first surface 440. For forming the first insulating film 141 on the first surface 440 using the thermal sprayer 500, a method similar to the first method of manufacturing the stage 122 shown in the first embodiment can be used. The movement of the thermal sprayer 500 is continuous and unidirectional. Thus, by forming the first insulating film 141 from the second surface 442 to the first surface 440, the first insulating film 141 can be uniformly formed on the second surface 442 and the first surface 440.

As described above, by forming the first insulating film 141 on each surface, the first insulating film 141 can be provided on the support plate 140. Further, since joining the support plate 140 and the electrostatic chuck 170 is the same as that in FIG. 1A shown in the first embodiment, the explanation thereof is omitted here. As described above, the stage 122 can be manufactured by the second manufacturing method.

As described above with reference to FIGS. 2A, 8A, 8B, 8C, and 1A, by forming the first insulating film 141 on the third surface 444, forming the first insulating film 141 on the second surface 442, and forming the first insulating film 141 on the first surface 440 while moving the thermal sprayer 500 continuously and in one direction, the first insulating film 141 can be uniformly formed by the third surface 444, the second surface 442, and the first surface 440 of the support plate 140. It is further possible to suppress the generation of a gap or void in the corner portion between the third surface 444 and the second surface 442 and the corner portion between the second surface 442 and the first surface 440. Consequently, the first insulating film 141 formed on the third surface 444, the corner portion between the third surface 444 and the second surface 442, the second surface 442, the corner portion between the second surface 442 and the first surface 440, and the first surface 440 become a uniform film substantially free of gaps or voids. Therefore, since the first insulating film 141 is densely formed on the support plate 140, the dielectric breakdown voltage of the support plate 140 is further improved. Therefore, by applying the present invention to the stage and the method of manufacturing the stage, it is possible to provide a stage and a method of manufacturing the stage having a high withstand voltage.

The method of manufacturing the stage according to the present embodiment is not limited to the above-described manufacturing method.

The method of manufacturing the stage according to the present embodiment may be, for example, a manufacturing method of forming the first insulating film 141 on the first surface 440, forming the first insulating film 141 on the second surface 442, and forming the first insulating film 141 on the third surface 444, while moving the thermal sprayer 500 continuously and in one direction. In the manufacturing method of forming the first insulating film 141 on the first surface 440, forming the first insulating film 141 on the second surface 442, and forming the first insulating film 141 on the third surface 444 while moving the thermal sprayer 500 continuously and in one direction, the first insulating film 141 is formed densely on the support plate 140 similar to the manufacturing method described above. As a result, the dielectric breakdown voltage of the support plate 140 is further improved.

In the method of manufacturing the stage according to the present embodiment, for example, forming the first insulating film 141 on the third surface 444 may be a first thermal spraying and continuously forming the first insulating film 141 on the second surface 442 and forming the first insulating film 141 on the first surface 440 may be a second thermal spraying. Furthermore, in the method of manufacturing the stage according to the present embodiment, the first thermal spraying and the second thermal spraying may be alternately performed, the first thermal spraying and the second thermal spraying may be alternately repeated, the second thermal spraying and the first thermal spraying may be alternately performed, and the second thermal spraying and the first thermal spraying may be alternately repeated. By alternately repeating the first thermal spraying and the second thermal spraying, variations in the thickness of the insulating film of the stage are further suppressed. As a result, it is possible to provide a stage in which the insulating film is formed more uniformly.

In the method of manufacturing the stage according to the present embodiment, after performing the first thermal spraying and the second thermal spraying alternately, the first thermal spraying and the second thermal spraying may be performed continuously, and after repeating the first thermal spraying and the second thermal spraying alternately, the first thermal spraying and the second thermal spraying may be performed continuously and repeatedly. Similarly, in the case where the second thermal spraying is performed in advance, after performing the second thermal spraying and the first thermal spraying alternately, the first thermal spraying and the second thermal spraying may be performed continuously, and after repeating the second thermal spraying and the first thermal spraying alternately, the first thermal spraying and the second thermal spraying may be performed continuously and repeatedly. By performing the first thermal spraying and the second thermal spraying alternately and then performing the first thermal spraying and the second thermal spraying continuously, it is possible to further suppress variations in the thickness of the insulating film of the stage and further suppress the generation of a gap or a void in the corner portion of the stage.

### 3. Third Embodiment

In this embodiment, a film processing device provided with the stage 122 will be described as an example. Description of the same or similar configuration as that of the first embodiment or the second embodiment may be omitted.

In FIG. 9, a cross-sectional view of an etching device 200 which is one of the film processing devices is shown. The etching device 200 can perform dry etching on various films. The etching device 200 has the chamber 202. The chamber 202 provides a space for etching a film, such as a conductor, insulator, or semiconductor, formed on the substrate.

An exhaust device 204 is connected to the chamber 202, so that the inside of the chamber 202 can be set to a reduced-pressure atmosphere. The chamber 202 is further provided with an introduction tube 206 for introducing a reaction gas, and the reaction gas for etching is introduced into the chamber via a valve 208. Examples of the reaction gas include fluorine-containing organic compounds such as carbon tetrafluoride (CF₄), octafluorocyclobutane (c-C₄F₈), decafluorocyclopentane (c-C₅F₁₀), and hexafluorobutadiene (C₄F₆).

A microwave source 212 may be provided at the top of the chamber 202 via a waveguide 210. The microwave source 212 has an antenna for supplying microwaves, and outputs a high-frequency microwave such as a 2.45 GHz microwave and a 13.56 MHz radio wave (RF). The microwave generated by the microwave source 212 propagates by the waveguide 210 to the top of the chamber 202 and is introduced into the chamber 202 via a window 214 containing quartz or a ceramic, or the like. The reaction gas is converted into plasma by the microwave, and etching of the film proceeds by electrons, ions, and radicals contained in the plasma.

The stage 122 according to an embodiment of the present invention is provided in a lower portion of the chamber 202 in order to arrange a substrate. The substrate is arranged on the stage 122. A power supply 224 is connected to the stage 122, and a voltage corresponding to a high frequency power is applied to the stage 122, and an electric field produced by microwaves is formed on the surface of the stage 122 in a direction perpendicular to the substrate surface. A magnet 216, a magnet 218, and a magnet 220 can be further provided on the top and sides of the chamber 202. The magnet 216, the magnet 218, and the magnet 220 may be permanent magnets, or electromagnets having electromagnet coils. The magnet 216, the magnet 218, and the magnet 220 create magnetic field components parallel to the stage 122 and the surface of the substrate, and in conjunction with the electric field produced by microwaves, electrons in the plasma receive a Lorentz force and resonate and are bound to the stage 122 and the surface of the substrate. As a result, high-density plasmas can be generated on the surface of the substrate.

For example, a heater power supply 230 controlling the sheath heater is connected when the stage 122 is equipped with a sheath heater. The stage 122 may also be connected in any configuration to a power supply 226 for the electrostatic chuck for securing the substrate to the stage 122, the temperature controller 228 for controlling the temperature of the medium recirculated into the stage 122, and a rotating control device (not shown) for rotating the stage 122.

As described above, the stage 122 according to an embodiment of the present invention is used in the etching device 200. By using the stage 122, the substrate can be uniformly heated, and the heating temperature can be precisely controlled. By using the stage 122, it is possible to improve the dielectric breakdown voltage of the stage. By using the stage 122, the withstand voltage for the voltage applied to the substrate is improved. Therefore, by using the etching device 200, a contact having a high aspect ratio or a film having a high aspect ratio can be formed. Therefore, the etching device 200 enables uniform etching of the various films provided on the substrate.

### 4. Fourth Embodiment

This embodiment describes the percentage of the gaps or voids 446 in the corner portion of the stage according to an embodiment of the present invention, and the dielectric breakdown voltage of the stage according to an embodiment of the present invention. Description of the same or similar components as those of the first to third embodiments may be omitted.

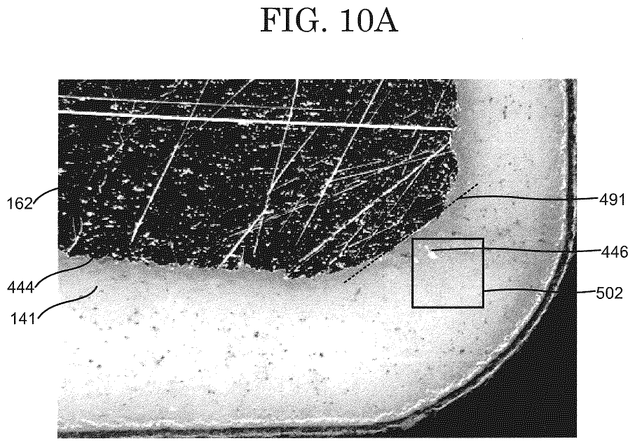

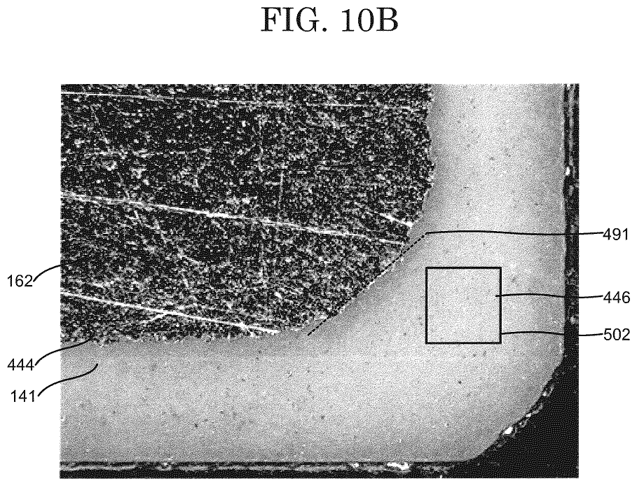

As shown in FIGS. 10A and 10B, the gaps or voids 446 are shown as black dots. In FIGS. 10A and 10B, there are no large gaps or voids 446 as there are in the corner portion in the conventional stage as shown in FIG. 4C. In FIG. 10A and FIG. 10B, a region 502 of 200 μm×200 μm is shown. In FIG. 10A, the ratio of the area of the gaps or voids 446 to the area of the region 502 is 4.33%. In FIG. 10B, the ratio of the area of the gaps or voids 446 to the area of the region 502 is 0.49%. That is, the ratio of the area of the gaps or voids 446 to the area of the region 502 of the corner portion formed by the first and second manufacturing methods is dramatically reduced compared to the conventional area ratio.

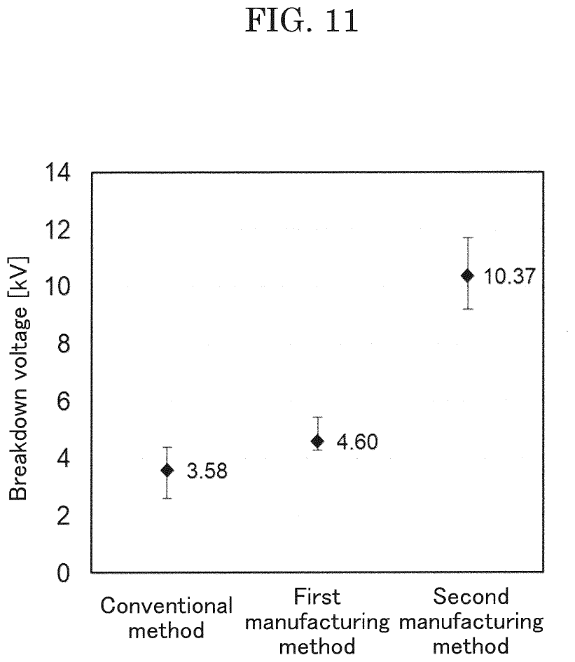

Next, as shown in FIG. 11, the dielectric breakdown voltage of the conventional stage was 3.58 kV, the dielectric breakdown voltage in the case where the stage according to an embodiment of the present invention was manufactured by the first manufacturing method was 4.60 kV, and the dielectric breakdown voltage in the case where the stage was manufactured by the second manufacturing method was 10.37 kV. The dielectric breakdown voltage in the case where the stage was manufactured by the first manufacturing method is 1 kV larger than the dielectric breakdown voltage in the conventional stage, and the dielectric breakdown voltage in the case where the stage was manufactured by the second manufacturing method is about three times larger than the dielectric breakdown voltage in the conventional stage.

### 5. Fifth Embodiment

In this embodiment, the stage 124 according to an embodiment of the present invention will be described. Description of the same or similar components as those of the first to fourth embodiments may be omitted.

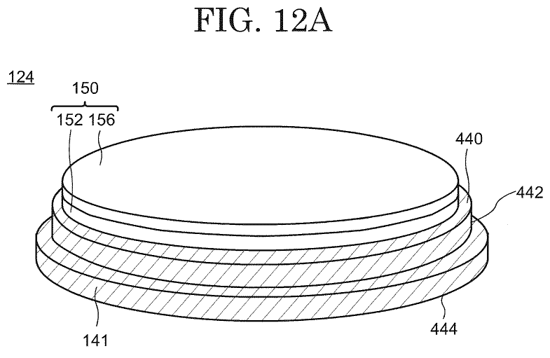

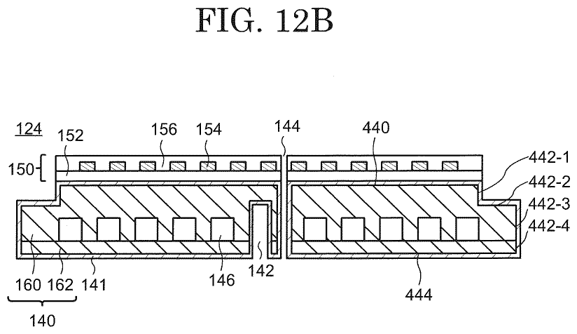

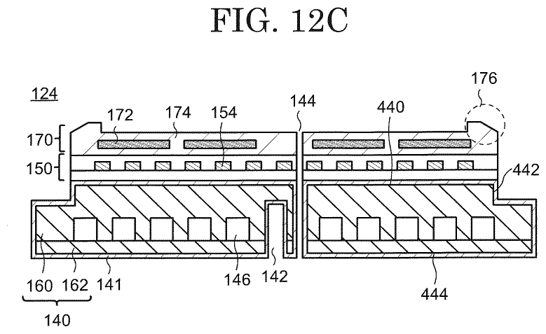

FIGS. 12A to 12C shows a perspective view or a cross-sectional view of a stage 124. The configuration of the stage 124 is different from that of the stage 122 shown in the first embodiment in that it has a configuration of a heater layer 150. In the following description of the configuration of the stage 124, mainly points different from the configuration of the stage 122 will be described. The first to fourth embodiments may be implemented by appropriately replacing the stage 122 described in the first to fourth embodiments with the stage 124 described in this embodiment.

As shown in FIG. 12A and FIG. 12B, the stage 124 has the support plate 140, and the heater layer 150 is provided there above.

At the stage 124, the temperature of the support plate 140 may be controlled by flowing the temperature-controlled medium through the groove 146 by the temperature controller 228 shown in FIG. 9 described above. However, the response of temperature control by a liquid medium is slow, and precise temperature control is relatively difficult. Therefore, it is preferable to roughly control the temperature of the support plate 140 using the medium and precisely control the temperature of the substrate using a heater wire 154 in the heater layer 150. This enables not only precise temperature control but also temperature adjustment of the stage 124 at high speed.

The heater layer 150 mainly has three layers. In particular, the heater layer 150 has a second insulating film 152, the heater line 154 on the second insulating film 152, and a third insulating film 156 on the heater wire 154 (FIG. 12B). Only one heater wire 154 may be provided in the heater layer 150, or a plurality of heater wires 154 may be provided, each of which may be independently controlled by the heater power supply 230 illustrated in FIG. 9. The heater wire 154 is electrically insulated by the second insulating film 152 and the third insulating film 156. Power supplied from the heater power supply 230 heats the heater wire 154, which controls the temperature of the stage 124.

The second insulating film 152 and the third insulating film 156 may include an inorganic insulator. Since the inorganic insulator is shown in the first embodiment, a description thereof is omitted here. The second insulating film 152 and the third insulating film 156 can be formed using the thermal spraying method. Since the thermal spraying method is shown in the first embodiment, the description thereof is omitted here.

The heater wire 154 may include a metal that generates heat by electric conduction. Specifically, the heater wire 154 may include a metal selected from tungsten, nickel, chromium, cobalt, and molybdenum. The metal may be an alloy containing these metals, for example an alloy of nickel and chromium, an alloy containing nickel, chromium, and cobalt.

The heater wire 154 is preferably formed by disposing a metal film formed by a sputtering method, an organometallic CVD (MOCVD) method, an evaporation method, a printing method, an electroplating method, or the like, or a metal foil processed separately by etching on the second insulating film 152. When forming the heater wire 154 using the thermal spraying method, it is difficult to ensure a uniform density, thickness, and width over the entire heater wire 154, whereas, in the case of the metal film or metal foil described above, it is possible to form the small heater wire 154 having small variations in these physical parameters. This makes it possible to precisely control the temperature of the stage 124 and reduce the temperature distribution.

Furthermore, since the alloy described above has a higher volume resistivity as compared with a metal alone, the layout of the heater wire 154, i.e., when the planar shape is the same, it is possible to increase the thickness of the heater wire 154 as compared with the case of using a metal alone. Therefore, it is possible to reduce the variation in the thickness of the heater wire 154, and it is possible to realize a smaller temperature distribution.

Optionally, the stage 124 may have one or more through hole(s) 144 that simultaneously penetrates the support plate 140 and the heater layer 150. A helium introduction tube may be provided in the chamber 202 shown in FIG. 9 to allow a gas with high thermal conductivity, such as helium, to flow through the through hole 144. This allows the gas to flow through the gap between the stage 124 and the substrate, and efficiently convey thermal energy of the stage 124 to the substrate. In an embodiment of the present invention, although an example is shown in which the first insulating film 141 is provided on the inner wall of the through hole 144, the first insulating film 141 may be provided on a part of the inner wall of the through hole 144.

As illustrated in FIG. 12C, the stage 124 may further have the electrostatic chuck 170 as a mechanism for securing the substrate on the stage 124. Since the electrostatic chuck 170 is shown in the first embodiment, a description thereof will be omitted.

As described above, the stage according to an embodiment of the present invention has fewer gaps or voids compared to the conventional stage and has a large dielectric breakdown voltage. Therefore, by applying the manufacturing method according to an embodiment of the present invention, a stage having a high withstand voltage and a method of manufacturing the stage can be provided.

Each of the embodiments described above as an embodiment of the present invention can be appropriately combined and implemented as long as they do not contradict each other. On the basis of each embodiment, those in which a person skilled in the art has appropriately added, deleted, or changed the design of the constituent elements are also included in the scope of the present invention as long as the gist of the present invention is provided.

It is understood that other operational effects different from those provided by the respective embodiments described above, or those which can be easily predicted by those skilled in the art, apparent from the description herein, are naturally brought about by the present invention.

1. A stage comprising:
a base material having a first surface and a second surface adjacent to the first surface; and
an insulating film including a plurality of particles, each of particles having a flat surface,
wherein
the flat surface included in the insulating film is provided along the first surface and the second surface.

2. The stage according to claim 1, wherein
the base material includes a third surface in a direction 180 degrees opposite to the first surface, and
the flat surface included in the insulating film is provided along the third surface.

3. The stage according to claim 1, wherein
a surface obtained by extending the first surface and a surface obtained by extending the second surface intersect at 90 degrees.

4. The stage according to claim 1, wherein
a ratio of an area of a void to a predetermined area of the insulating film is 5% or less.

5. The stage according to claim 1, wherein
the base material has a flow path through which a liquid flows.

6. The stage according to claim 1, wherein
an electrostatic chuck is provided on the insulating film.
